(19) United States
(12) Patent Application Publication
(10) Pub. No.: US 2014/0376165 A1
(43) Pub. Date: Dec. 25, 2014

(54) TRANSFER FILM, METHOD FOR TRANSFERRING THE SAME AND ELECTRONIC DEVICE

(71) Applicant: SAMSUNG ELECTRONICS CO., LTD., Suwon-si (KR)

(72) Inventors: Tai Hoon HAN, Suwon-si (KR); Il Yong SEONG, Hwaseong-si (KR); Sung Woon YOON, Suwon-si (KR); Kyo ree Lee, Seoul (KR); Mi Ran JEONG, Suwon-si (KR); Ah Hyun BAE, Hwaseong-si (KR)

(73) Assignee: SAMSUNG ELECTRONICS CO., LTD., Suwon-si (KR)

(21) Appl. No.: 14/301,804

(22) Filed: Jun. 11, 2014

(30) Foreign Application Priority Data
Jun. 19, 2013 (KR) 10-2013-0070385

(51) Int. Cl. H05K 7/02; H05K 13/00; H05K 5/00

(52) U.S. Cl. CPC H05K 7/02; H05K 5/0017; H05K 13/00
USPC 361/679.01; 428/41.6; 428/40.4; 156/247

(57) ABSTRACT

A transfer film that shields light to prevent a display image from being transmitted to a part of a window, a method for transferring the same and an electronic device are provided. The electronic device includes a transfer film having a laminated structure, wherein the transfer film includes a base layer, a release layer removable from the base layer, a printing layer to implement a pattern and a color, and an adhesion layer adhered by pressure to a window provided to view visual information output from a display.

### CROSS-REFERENCE TO RELATED APPLICATIONS

This application is related to, and claims the priority benefit of Korean Patent Application No. 10-2013-0070385, filed on Jun. 19, 2013, in the Korean Intellectual Property Office, the disclosure of which is incorporated herein by reference.

### BACKGROUND

1. Field

Embodiments relate to a transfer film that shields light to prevent a display image from being transmitted to a part of a window, a method for transferring the same and an electronic device.

2. Description of the Related Art

In display panels (hereinafter, referred to as “panels”) such as LCDs, PDPs or LEDs, a protective material, e.g., glass may be mounted on a front surface of a panel that outputs an image and functions to protect the panel and shield an edge of the panel.

Such a front protective glass may be attached to an edge of a display panel using a fixer. An operation button, or the like, may be mounted under the edge of the front protective glass. A light-shielding unit having a band-like shape implementing dark color may be thus formed at the edge to shield light and thereby hide a rear surface.

For such light-shielding treatment, a light-shielding layer may be formed by printing a dark color using a silkscreen or pad printing method.

In a case in which the light-shielding layer is formed using a silkscreen or pad printing method, when a single-color light-shielding unit is implemented, a design may be simple, and printing may be repeated according to implemented color and design so as to form a light-shielding layer having various colors. However, process defects are increased due to a repetition of a printing process. A drying process may be added according to a number of printing processes, and, an overall process time is thus lengthened.

### SUMMARY

It is an aspect of an exemplary embodiment to provide a transfer film that has an improved structure so as to be transferred to a window under room temperature and pressure conditions, a method for transferring the same and an electronic device.

It is an aspect of an exemplary embodiment to provide a transfer film that has an improved structure to enable slimness, a method for transferring the same and an electronic device.

Additional aspects are set forth in part in the description which follows and, in part, will be obvious from the description, or may be learned by practice of the invention.

In accordance with an aspect of an exemplary embodiment, an electronic device is provided including a transfer film having a laminated structure, wherein the transfer film includes a base layer, a release layer removable from the base layer, a printing layer to implement a pattern, and an adhesion layer adhered by pressure to a window provided to view visual information output from a display.

The adhesion layer may be adhered to a rear surface of the window under room temperature and pressure conditions.

The window may include a first region transmitting light, and a second region that is non-transparent, is surrounded by the first region and has an area corresponding to the display.

The printing layer may implement various patterns and colors. The printing layer may have various patterns or colors at a position corresponding to the second region.

The adhesion layer may be adhered to a rear surface of the window at room temperature by pressurization to reflect the various patterns or colors provided in the printing layer in the second region of the window, and the base layer may be removed from the release layer.

The base layer may include at least one of polyethylene terephthalate (PET) and polyethylene terephthalate glycol (PETG).

The release layer may include at least one of a melamine-based release agent and a silicone-based release agent.

The printing layer may include at least one layer and may include at least one of a flat printing layer, a pattern printing layer and a deposition layer, and the deposition layer may include at least one of an inorganic substance and a metal to provide a metallic texture.

The adhesion layer may be adhered to the window at room temperature by pressurization and may include a viscoelastic substance exhibiting permanent adhesion.

The viscoelastic substance may include a pressure sensitive adhesive (PSA).

In accordance with an aspect of an embodiment, a transfer film includes a base layer, a release layer removably laminated on the base layer, a printing layer laminated on the release layer to provide a pattern, and an adhesion layer laminated on the printing layer, the adhesion layer being adhered to a glass substrate for display panels upon application of pressure.

The base layer may include at least one of polyethylene terephthalate (PET) and polyethylene terephthalate glycol (PETG).

The release layer may include at least one of a melamine-based release agent and a silicone-based release agent.

The printing layer may provide various patterns and colors. The printing layer may have a structure in which a flat printing layer, a pattern printing layer and a deposition layer are laminated in order.

The deposition layer may include at least one of an inorganic substance and a metal to provide a metallic texture.

The deposition layer may include at least one layer.

The pattern printing layer may include a UV pattern layer.

The adhesion layer may be adhered to the glass substrate for display panels at room temperature by application of low pressure and may include a viscoelastic substance exhibiting permanent adhesion.

The viscoelastic substance may include a pressure sensitive adhesive (PSA).

The transfer film may further include a protective layer provided on the adhesion layer to prevent attachment of foreign matter to the adhesion layer.

In accordance with an aspect of an embodiment, a method for transferring a transfer film includes supplying a transfer film having a structure in which a base layer, a release layer, a printing layer and an adhesion layer are laminated in this order, and a substrate to a transfer device, bring the transfer film in contact with a rear surface of the substrate, adhering the adhesion layer to the glass substrate for display panels when pressure is applied to the transfer film, transferring a pattern and a color provided in the printing layer to the substrate, and removing the base layer.

The pattern may be a plurality of plurality of patterns and the color may be a plurality of colors. The substrate may be a glass substrate for display panels.

### BRIEF DESCRIPTION OF THE DRAWINGS

These and/or other aspects of the invention will become apparent and more readily appreciated from the following description of the embodiments, taken in conjunction with the accompanying drawings of which:

FIG. 1 is a perspective view illustrating a front surface of an electronic device according to an embodiment;

FIG. 2 is a perspective view illustrating a rear surface of the electronic device according to the present embodiment;

FIG. 3 is an exploded perspective view illustrating an electronic device according to an exemplary embodiment;

FIG. 4 is an exploded perspective view illustrating a display panel of an electronic device according to an embodiment;

FIG. 5 is a schematic view illustrating a transfer film coupled to a window in the electronic device according to an embodiment;

FIG. 6 is a schematic view illustrating a configuration in which a flat printing layer, a pattern printing layer and a deposition layer are provided in the transfer film according to an embodiment; and

FIG. 7 is a schematic view illustrating a process for transferring the transfer film according to an embodiment.

### DETAILED DESCRIPTION

Hereinafter, embodiments are described in detail with reference to the accompanying drawings. An exemplary mobile electronic device is described as an example of an electronic device. However, according to an exemplary embodiment applies to other devices, for example, a portable laptop device, etc.

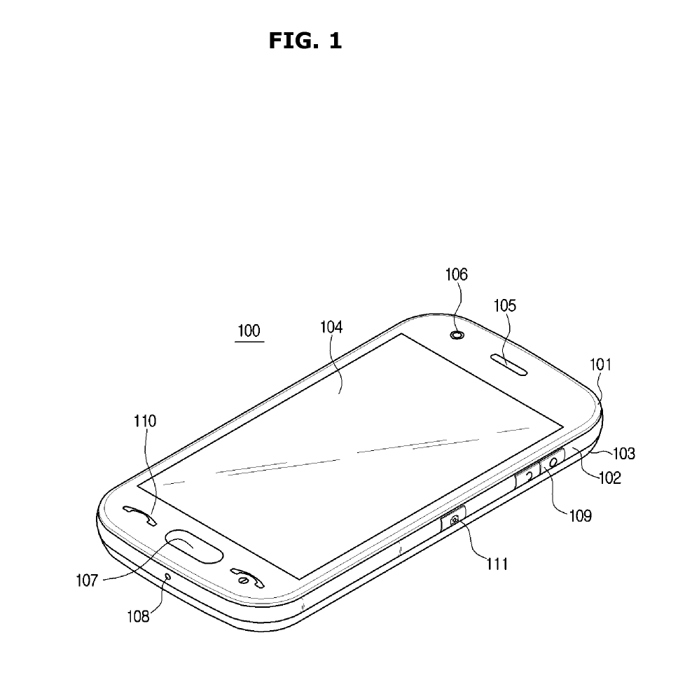

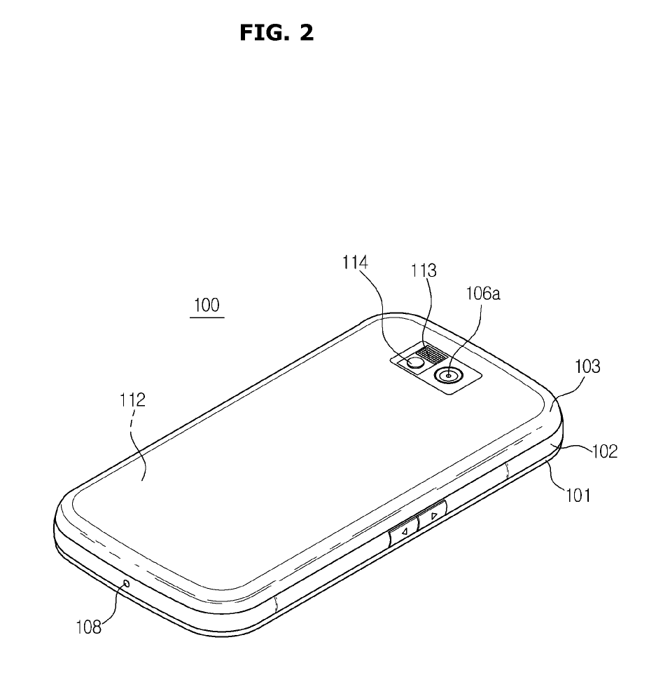

FIG. 1 is a perspective view illustrating a front surface of an electronic device according to an embodiment. FIG. 2 is a perspective view illustrating a rear surface of the electronic device according to an embodiment.

As illustrated in FIGS. 1 and 2, the electronic device 100 includes a body, e.g., a bar-shaped body. The body of the electronic device 100 is not limited to the bar shape and may have other shapes, e.g., oval or square. Exemplary bodies may include various structures such as a slide-, a folder-, a swing- and a swivel-type structures that may be movably coupled.

The body includes a case (such as, for example, a casing, housing or cover) to constitute an outer appearance. The body may include a front case 101, a rear case 102 and a battery cover 103. Various electronic components may be accommodated in a space, for example, formed between the front case 101 and the rear case 102. At least one intermediate case may be interposed between the front case 101 and the rear case 102.

A case may be formed by injecting a material, e.g., a synthetic resin, or be formed of a material, e.g., a metal material, for example, stainless steel (STS), aluminum (Al) or titanium (Ti).

A display module 104, a sound output unit 105, a camera 106, a user input unit 107, a microphone 108, an interface 109, and the like, may be disposed in the electronic device body, e.g., at the front case 101.

The display module 104 may occupy most of a main surface of the front case 101. The sound output unit 105 and the camera 106 may be disposed in a region adjacent to one end of the display module 104. A user input unit 107 and a microphone 108 may be disposed in a region adjacent to the other end thereof. The user input unit 107, the interface 109 and the like may be disposed, for example, on sides of the front case 101 and the rear case 102. However, the arrangements may vary.

The user input unit 107 may be manipulated to input a command to control an operation of the electronic device 100 and includes a plurality of manipulating units 110 and 111. The manipulating units 110 and 111 may be referred to as a “manipulating portion” and may adopt a manner, e.g., a tactile manner that enables manipulation via application of a user contact.

Contents input via the first manipulating unit 110 and/or the second manipulating unit 111 may be variably set. For example, the first manipulating unit 110 may input a command such as start, end or scroll. The second manipulating unit 111 may input a command such as volume control of a sound output from the sound output unit 105 or conversion into touch sense mode of the display module 104. The display module 104 may form a touch screen together with a touch sensor. A touch screen is an example of a user input unit.

As illustrated in FIG. 2, a camera 106a may be mounted, for example, on the rear case 102. The camera 106a has a photographing direction substantially opposite to the camera 106 and may be a camera that has a pixel number different from that of the camera 106.

For example, in the case of video call or the like, the camera 106 may have a low pixel number to obtain an image of a user face and transfer the image to a counterpart, and the camera 106a may have a high pixel number since it does not predominantly transfer an image of a general object immediately after photographing. The cameras 106 and 106a may be rotatably or pop-up mounted on the electronic device body.

A flash 113 and a mirror 114 may be disposed adjacent to the camera 106a. The flash 113 emits light toward an object when the object is photographed (imaged) using the camera 106a. The mirror 114 allows a user, for example, to see his image reflected therein, when the user photographs themselves (self-photographs) using the camera 106a.

A sound output unit may be disposed on the rear surface of the electronic device body. The sound output unit of the rear surface may implement a stereo function together with the sound output unit 105 of the front surface and may be used to implement a speakerphone mode upon calling.

A power supply 112 to supply power to the electronic device 100 may be mounted on the electronic device body. The power supply 112 may be accommodated in the electronic device body or may be directly detached from the outside of the electronic device body.

A touch sensor to sense touch may be mounted on the rear case 102. The touch sensor may also be of a light-transmission type, like the display module 104. When the display module 104 outputs visual information at both surfaces thereof, the touch sensor also senses the visual information. The visual information output at both surfaces may be controlled, e.g., controlled entirely by the touch sensor. A display may be mounted on the touch sensor and a touch screen may be disposed at the rear case 102.

The touch sensor may operate mutually with the display module 104 of the front case 101. The touch sensor may be disposed at the rear of the display module 104 in parallel. Such a touch sensor may have a size equivalent to, or smaller than, that of the display module 104.

An antenna for transmission and/or an antenna for receiving a broadcast signal may be mounted on the electronic device body.

An antenna for implementing near field communication may be disposed in the electronic device body.

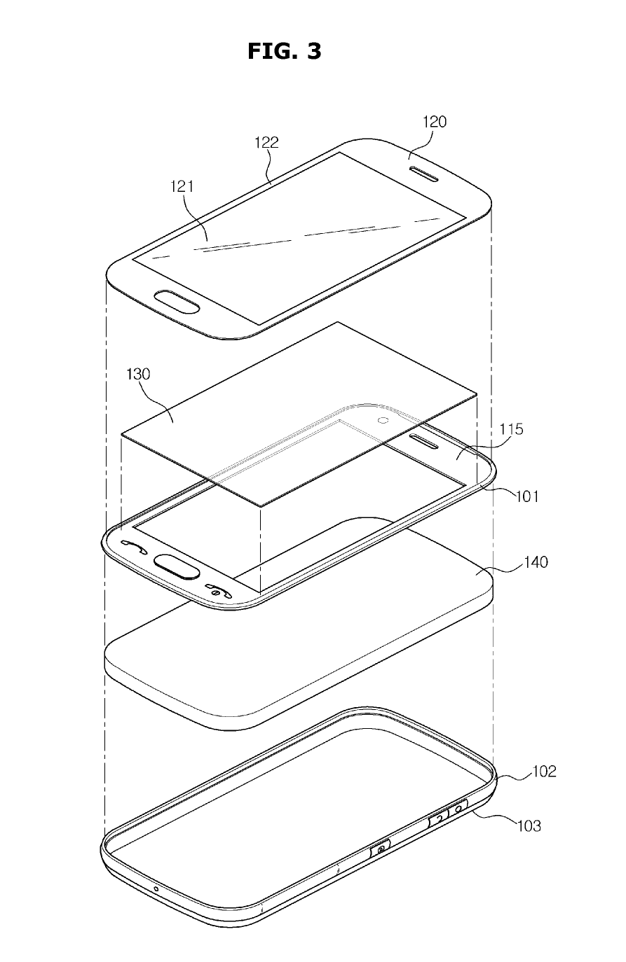

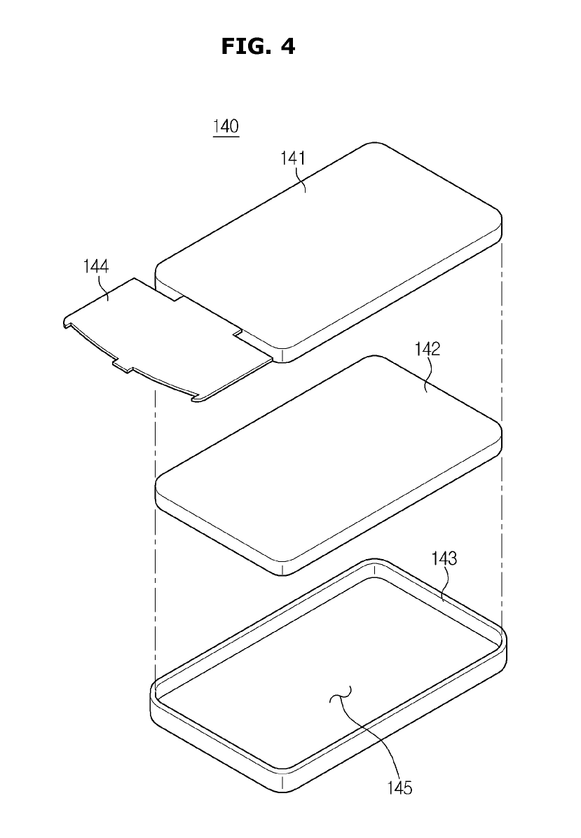

FIG. 3 is an exploded perspective view illustrating an electronic device according to an embodiment, and FIG. 4 is an exploded perspective view enlargedly illustrating a display panel of the electronic device according to an embodiment.

As illustrated in FIG. 3, the electronic device may include a window 120, a touch sensor 130, a front case 101, a display panel 140 and a rear case 102.

The front case 101 may be provided with a bezel unit 115 on which the window 120 may be mounted.

The bezel unit 115 may be provided separately with the front case 101.

The window 120 may be coupled to one surface of the front case 101. The window 120 may be made of a material transmitting light, for example, a light-transmitting synthetic resin or reinforced glass.

The window 120 may include a first region 121 and a second region 122.

The first region 121 transmits light, while the second region 122 surrounding the first region 121 and does not transmit light.

The first region 121 may be formed in the center of the window 120, while the second region 122 may be formed at an edge of the window 120.

The second region 122 shields light to prevent transmission of an image of the display 141.

The display 141 may be mounted on the rear surface of the window 120. The display 141 is disposed to correspond to the window 120 and displays visual information to the outside through the first region 121.

The first region 121 may have an area equivalent to the display 141. Accordingly, the user sees visual information output from the display 141. The window 120 and the display 141 may be configured with the display module (104, see, for example, FIG. 1).

A touch sensor 130 to sense touch input may be mounted on the window 120. The touch sensor 130 may be disposed to correspond to the window 120 and may be formed to sense a touch point of the window 120.

The touch sensor 130 may be made of a light-transmitting material and converts variation of pressure, voltage, capacitance or the like generated in a specific area of the window 120 into an electrical input signal.

The touch sensor 130 may be a capacitive sensor. A capacitive sensor is only an example of the touch sensor 130 and the touch sensor 130 is not limited thereto.

A display panel 140 may be mounted on the rear case 102.

As illustrated in FIG. 4, the display panel 140 may include a display 141, a backlight unit 142 and a module fixing unit 143.

The display 141 converts image data input from a control unit of a portable electronic device into an analog signal and displays the analog signal through a flexible printed circuit board (FPCB) 144. The display 141 may be implemented by a liquid crystal display (LCD).

The backlight unit 142 may be mounted on a lower surface of the display 141 and emits light to the display 141. That is, the display 141 displays an image while controlling, for example, a transmission level and color of light emitted from the backlight unit 142.

The module fixing unit 143 functions to fix the display 141 and the backlight unit 142. Such a module fixing unit 143 may form an accommodation area 145 to accommodate the display 141 and the backlight unit 142. That is, the display 141 and the backlight unit 142 may be accommodated in the accommodation area 145 and are protected thereby.

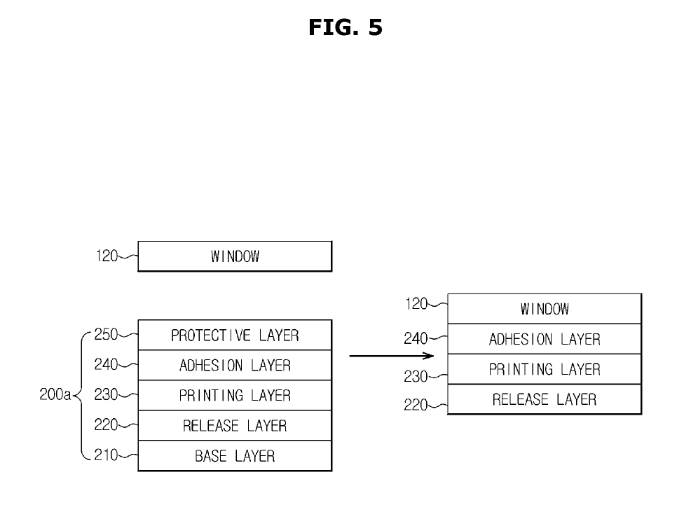

FIG. 5 is a schematic view illustrating a transfer film coupled to a window in an electronic device according to an embodiment.

The transfer film 200a may include a base layer 210, a release layer 220, a printing layer 230 and an adhesion layer 240.

The transfer film 200a may have a structure in which the base layer 210, the release layer 220, the printing layer 230 and the adhesion layer 240 are laminated in order.

The base layer 210 functions, for example, to maintain the shape of the transfer film 200a.

The base layer 210 may comprise at least one resin of polyethylene terephthalate (PET) and polyethylene terephthalate glycol (PETG).

The base layer 210 may have a thickness of 50 μm to 100 μm.

When the thickness of the base layer 210 is excessively small, contraction of the base layer 210 may increase.

The release layer 220 functions, for example, to enable easy removal of the base layer 210.

The release layer 220 may be selected, for example, from wax, silicone, Teflon, melamine and urethane resins and combinations thereof.

The release layer 220 may comprise at least one of a melamine-based release agent and a silicone-based release agent.

The release layer 220 may have a thickness of 1 μm to 2 μm.

The printing layer 230 may function to form various patterns and colors.

The printing layer 230 may have various patterns and colors at a position corresponding to the second region 122 of the window 120.

The printing layer 230 may comprise an acrylic resin, a polyurethane resin, a melamine resin or a polyamide resin and comprise various pigments or dyes.

The printing layer 230 may improve printing effects through addition of a stabilizer, an anti-blocking agent and a quencher according to patterns.

The printing layer 230 may include at least one of a flat printing layer 231, a pattern printing layer 233 and a deposition layer 232.

The flat printing layer 230 includes a specific resin and a pigment having light resistance and heat resistance. The specific resin may be a thermosetting acrylic resin and the pigment may be selected from well-known pigments.

A pattern printing layer 230 may include a natural marble pattern, a geometric pattern, a wood pattern, or a pattern similar to any other object, and the like.

The pattern printing layer 230 may include a UV pattern layer.

In addition, the deposition layer 232 may be formed to impart various metallic gloss to a printing surface of the printing layer 230.

The deposition layer 232 may comprise at least one of an inorganic substance and a metal.

The metal may be selected from aluminum, chromium, nickel, silver and the like.

The deposition layer 232 may have at least one layer.

The printing layer 230 may have a thickness of 20 μm or less.

The adhesion layer 240 functions to adhere the transfer film 200a to the window 120.

The adhesion layer 240 may have a thickness of 5 μm to 10 μm.

The adhesion layer 240 may comprise at least one of an adhesive agent and a sticking agent.

In the embodiments, a pressure-sensitive adhesive (PSA) may be used as the adhesion layer 240.

A pressure-sensitive adhesive is a viscoelastic substance that is adhered to a base material immediately upon application of pressure thereto and maintains adhesion thereafter.

The pressure-sensitive adhesive agent may comprise at least one compound selected from the group consisting of acryl, silicone, wax, carboxylic acid salts of polyamine amide, and a mixture of a paraffin mineral oil and a lipophilic component.

Any pressure-sensitive adhesive may be used without limitation to the compositions described above, so long as it adheres the transfer film 200a to the window 120 through application of pressure.

The transfer film 200a may further include a protective layer 250.

The protective layer 250 may be provided on the adhesion layer 240 and functions, for example, to prevent attachment of foreign matter to the adhesion layer 240.

The protective layer 250 may be removed and the transfer film 200a may be adhered to the window 120.

The transfer film 200a may be adhered to the rear surface of the window 120 under room temperature and pressure conditions.

Under room temperature and pressure conditions, for example, the adhesion layer 240 may be adhered to the rear surface of the window 120. Exemplary results of various tests of transfer film 200a are listed in TABLE 1.

TABLE 1

| | | Test | |
|---|---|---|---|
| | Test items | results | Test standards |
| 1 | X-cutting | Suitable | 1) Processed surface is not detached upon tape removal (defect: in a |
| | | | case of lattice pattern, an area of 2/3 or more of one unit cell is |
| | | | detached) |
| 2 | Pencil | Suitable | 1) A pencil hardness at which surface scratch occurs is 4H or more |
| | hardness | | (based on front surface, scratch is not present at pencil hardness of 3H) |
| | | | 2) A pencil hardness at which surface scratch occurs is 1H or more |
| | | | (based on rear surface) |
| | | | 3) A pencil hardness at which surface scratch of a HM-533 resin occurs |
| | | | is 3H or more |
| 3 | UV | Suitable | 1) Before/after testing, defects such as decolorization, discolorization |
| | | | and cracks are not present |
| | | | 2) In the case of AF coating, a contact angle variation relative to initial |
| | | | contact angle is ± about 10°, and coating peel is not externally observed |
| 4 | 50° C., 95% | Suitable | 1) Before/after testing, defects such as decolorization, discolorization, |
| | high- | | cracks, swelling, detachment or distortion, and nail scratches are not |
| | temperature | | present |
| | high- | | 2) Upon tape removal, detachment of processed surface does not occur |
| | humidity | | (defect: in the case of lattice pattern, an area of 2/3 or more of one unit |
| | | | cell is detached) |
| | | | 3) In the case of in-mold window having a touch key specification, |
| | | | resistance is 10 MΩ or more |
| | | | 4) In the case of AF coating, variation in contact angle relative to initial |
| | | | contact angle is ± about 10°, and coating peeling is not externally |
| | | | observed |
| 5 | Heat impact | Suitable | 1) Before/after testing, defects such as decolorization, discolorization, |
| | | | cracks, swelling, detachment or distortion, and nail scratches are not |
| | | | present |
| | | | 2) In the case of in-mold window, in an assembly state, separation and |
| | | | deformation are not observed |
| | | | 3) Upon tape removal, detachment of processed surface is not present |
| | | | (defect: in the case of lattice pattern, an area of 2/3 or more of one unit |
| | | | cell is detached) |
| | | | 4) In the case of in-mold window having a touch key specification, |
| | | | resistance is 10 MΩ or more |
| | | | 5) In the case of AF coating, variation in contact angle relative to initial |
| | | | contact angle is ± about 10°, and coating peel is not externally observed |
| 6 | Saline spray | suitable | 1) Before/after testing, defects such as decolorization, discolorization, |
| | | | cracks, swelling, detachment or distortion, and nail scratches are not |
| | | | present |
| | | | 2) Upon tape removal, detachment of processed surface is not present |
| | | | (defect: in the case of lattice pattern, an area of 2/3 or more of one unit |
| | | | cell is detached) |
| | | | 3) In the case of AF coating, variation in contact angle relative to initial |
| | | | contact angle is ± about 10°, and coating peel is not externally observed |
| 7 | 85° C., 85% | | 1) Before/after testing of printing surface, defects such as decolorization, |
| | high | | discolorization and cracks are not present |
| | temperature | | 2) Upon tape removal, detachment of processed surface does not occur |
| | high | | |
| | humidity | | |

As is apparent from the results of various tests laid out in Table 1 above, the transfer film 200a secures reliably and stably.

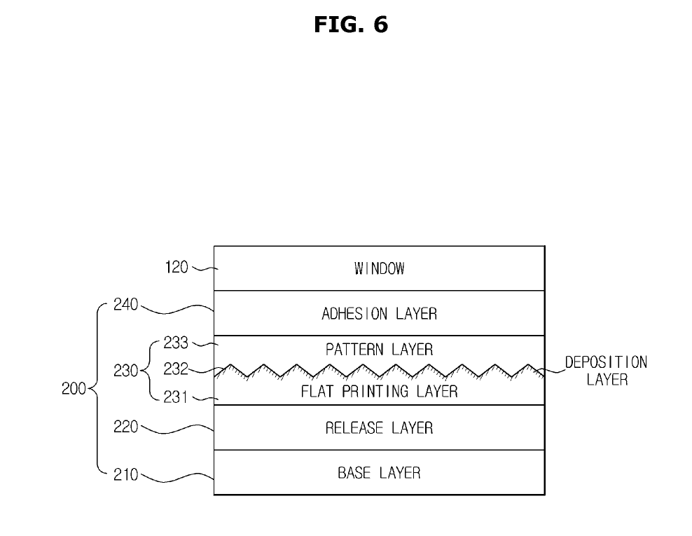

FIG. 6 is a schematic view illustrating a configuration in which a flat printing layer, a pattern printing layer and a deposition layer are provided in the transfer film according to an embodiment.

As illustrated in FIG. 6, when the printing layer 230 includes the flat printing layer 230, the deposition layer 232 and the pattern printing layer 230, the flat printing layer 230, the deposition layer 232 and the pattern printing layer 230 may be laminated in order.

The flat printing layer 230 may include at least one layer.

The deposition layer 232 may include at least one layer.

The pattern printing layer 230 may include at least one layer.

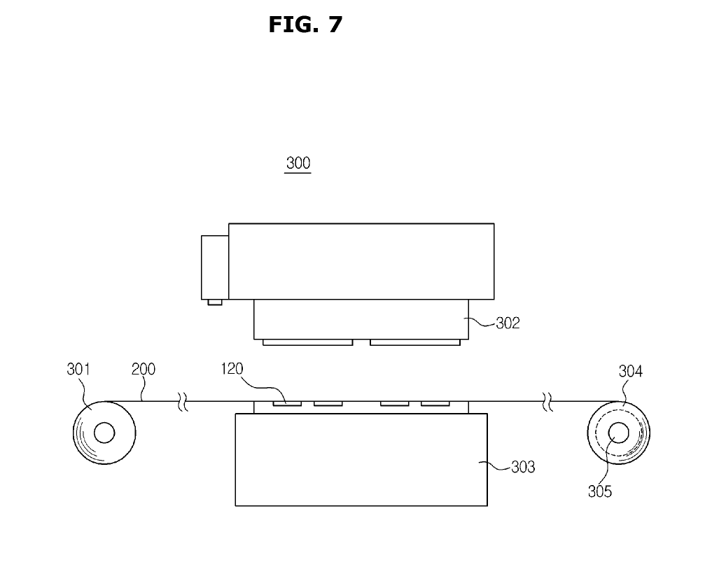

FIG. 7 is a schematic view illustrating a process of transferring the transfer film according to an embodiment.

A transfer device 300 may be used to transfer the transfer film 200 to the window 120.

The transfer device 300 may be provided at one side thereof with a supply unit 301 to supply the transfer film 200 and the supply unit 301 may be provided in an upper part thereof with a pressurization unit 302 that applies pressure to the window 120 and thereby transfers a pattern or color of the printing layer 230.

A support unit 303 to supply and support the window 120 is provided at a position corresponding to the pressurization unit 302.

One end of the transfer film 200 may be wound on a collection unit 304. The collection unit 304 functions to cover the transfer film 200 remaining after transfer to the window 120.

An exemplary printing process is disclosed. A transfer film 200 may be loaded in the supply unit 301 and one end thereof may be loaded in the collection unit 304. The window 120 may be supplied to the support unit 303.

A feed machine 305 of the collection unit 304 may be operated to move the transfer film 200 downward such that the pattern printed on the transfer film 200 may be disposed at a position corresponding to the window 120 and the pressurization unit 302.

The pressurization unit 302 may be operated at room temperature to compress the transfer film 200 against the window 120 and thereby transfer the pattern thereto.

After transfer, the pressurization unit 302 may be moved back and the window 120 supplied to the support unit 303 may be replaced. The feed machine 305 may be operated to move the transfer film 200 downward such that the pattern printed on the transfer film 200 may be disposed at a position corresponding to the window 120 and the pressurization unit 302.

The pressurization unit 302 may be operated to compress the transfer film 200 against the window 120 and thereby transfer the pattern.

Through repetition of this process, the pattern may be transferred to the window 120.

Transfer may be carried out on the rear surface of the window 120.

After the transfer, the base layer 210 of the transfer film 200 may be removed to realize slimness of products.

Since the transfer may be performed by pressurization at room temperature, deformation of the transfer film 200 by heat may be prevented.

Any transfer device may be used so long as it transfers the transfer film 200 to the window 120 by pressurization. The transfer device is not limited to this example.

Examples of the electronic device 100 include portable phones, smartphones, notebook computers, electronic devices for digital broadcast, personal digital assistants (PDAs), portable multimedia players (PMPs), navigators and the like.

The transfer film 200 of an embodiment may be used for products having a display unit such as the electronic device 100 as well as furniture, tiles, ceramics, clothes and the like.

According to an embodiment, detachment strength and shielding properties are satisfied without additional coating after printing and primer coating of the window, or transfer to the window.

The transfer may be performed at room temperature and pressure, and deformation of the transfer film by thermal transfer may be thus prevented.

An effect of thickness reduction may be obtained through removal of the base layer, and production cost reduction, production efficiency improvement and energy reduction effects are expected owing to simplified production process.

Although a few embodiments have been shown and described, it would be appreciated by those skilled in the art that changes may be made in these embodiments without departing from the principles and spirit of the invention, the scope of which is defined in the claims and their equivalents.

What is claimed is:

1. An electronic device comprising a transfer film having a laminated structure,
wherein the transfer film comprises:
a base layer;
a release layer removable from the base layer;
a printing layer to implement a pattern and a color; and
an adhesion layer adhered by pressure to a window provided to view visual information output from a display.

2. The electronic device according to claim 1, wherein the adhesion layer is adhered to a rear surface of the window under room temperature and pressure conditions.

3. The electronic device according to claim 1, wherein the window comprises:
a first region transmitting light; and
a second region that is non-transparent, is surrounded by the first region and has an area corresponding to the display.

4. The electronic device according to claim 3, wherein the printing layer has various patterns or colors at a position corresponding to the second region.

5. The electronic device according to claim 3, wherein the adhesion layer is adhered to a rear surface of the window at room temperature by pressurization to reflect the various patterns or colors provided in the printing layer in the second region of the window, and
the base layer is removed from the release layer.

6. The electronic device according to claim 1, wherein the base layer comprises at least one of polyethylene terephthalate (PET) and polyethylene terephthalate glycol (PETG).

7. The electronic device according to claim 1, wherein the release layer comprises at least one of a melamine-based release agent and a silicone-based release agent.

8. The electronic device according to claim 1, wherein the printing layer comprises at least one layer and comprises at least one of a flat printing layer, a pattern printing layer and a deposition layer, and the deposition layer comprises at least one of an inorganic substance and a metal to provide a metallic texture.

9. The electronic device according to claim 1, wherein the adhesion layer is adhered to the window at room temperature by pressurization and comprises a viscoelastic substance exhibiting permanent adhesion.

10. The electronic device according to claim 9, wherein the viscoelastic substance comprises a pressure sensitive adhesive (PSA).

11. A transfer film comprising:
a base layer;
a release layer removably laminated on the base layer;
a printing layer laminated on the release layer to provide a pattern and a color; and
an adhesion layer laminated on the printing layer, the adhesion layer being adhered to a substrate upon application of pressure.

12. The transfer film according to claim 11, wherein the base layer comprises at least one of polyethylene terephthalate (PET) and polyethylene terephthalate glycol (PETG).

13. The transfer film according to claim 11, wherein the release layer comprises at least one of a melamine-based release agent and a silicone-based release agent.

14. The transfer film according to claim 11, wherein the printing layer has a structure in which a flat printing layer, a pattern printing layer and a deposition layer are laminated in order.

15. The transfer film according to claim 14, wherein the deposition layer comprises at least one of an inorganic substance and a metal to provide a metallic texture.

16. The transfer film according to claim 15, wherein the deposition layer comprises at least one layer.

17. The transfer film according to claim 14, wherein the pattern printing layer comprises a UV pattern layer.

18. The transfer film according to claim 11, wherein the adhesion layer is adhered to the glass substrate for display panels at room temperature by application of low pressure and comprises a viscoelastic substance exhibiting permanent adhesion.

19. The transfer film according to claim 18, wherein the viscoelastic substance comprises a pressure sensitive adhesive (PSA).

20. The transfer film according to claim 11, further comprising a protective layer provided on the adhesion layer to prevent attachment of foreign matter to the adhesion layer.

21. The transfer film according to claim 11, wherein the substrate is a glass substrate for display panels.

22. A method for transferring a transfer film comprising:
supplying a transfer film having a structure in which a base layer, a release layer, a printing layer and an adhesion layer are laminated in order, and a substrate to a transfer device;
bringing the transfer film in contact with a rear surface of the substrate;
adhering the adhesion layer to the substrate when pressure is applied to the transfer film;
transferring a pattern and a color provided in the printing layer to the substrate; and
removing the base layer.

23. The method for transferring a transfer film according to claim 22, wherein the substrate is a glass substrate for display panels.
